(19) United States
(12) Patent Application Publication
(10) Pub. No.: US 2026/0081599 A1
(43) Pub. Date: Mar. 19, 2026

(54) SWITCH CIRCUIT

(71) Applicant: Murata Manufacturing Co., Ltd., Nagaokakyo-shi (JP)

(72) Inventors: Koudai SUGIYAMA, Nagaokakyo-shi (JP); Masamichi TOKUDA, Nagaokakyo-shi (JP)

(21) Appl. No.: 19/295,766

(22) Filed: Aug. 11, 2025

(30) Foreign Application Priority Data
Sep. 17, 2024 (JP) 2024-159766

(51) Int. Cl. H03K 17/687

(52) U.S. Cl. CPC H03K 17/6872

(57) ABSTRACT

A switch circuit includes a first switch that connects and disconnects a first signal path between a common terminal and a first selection terminal; a second switch that connects and disconnects a second signal path between the common terminal and a first node; a third switch that connects and disconnects a third signal path between the first node and a selection terminal; a fourth switch that connects and disconnects a fourth signal path between the common terminal and a second node; a fifth switch that connects and disconnects a fifth signal path between the second node and a third selection terminal; an inductor connected between the first and second nodes and a ground. Each of the quantity of switches on the second and third signal paths and the quantity of switches on the fourth and fifth signal paths is greater than the quantity of switches on the first signal path.

### CROSS REFERENCE TO RELATED APPLICATION

This application claims priority from Japanese Patent Application No. 2024-159766, filed on Sep. 17, 2024. The content of this application is incorporated herein by reference in its entirety.

### BACKGROUND OF THE DISCLOSURE

### 1. Field of the Disclosure

The present disclosure relates to a switch circuit.

### 2. Description of the Related Art

Japanese Unexamined Patent Application Publication No. 2018-029328 discloses a switch circuit that can transmit a radio frequency signal received by an antenna selectively to multiple signal paths.

### BRIEF SUMMARY OF THE DISCLOSURE

However, in the related-art technology described above, the quantity of switches varies depending on signal paths. For example, in FIG. 5 of Japanese Unexamined Patent Application Publication No. 2018-029328, the quantity of switches on a signal path passing through a multiplexer is greater than the quantity of switches on a signal path bypassing the multiplexer. If the quantity of switches varies depending on multiple signal paths, the transmission characteristics of the multiple signal paths may be degraded due to the difference in parasitic capacitance resulting from the off-capacitance of the switches. As used herein, “off-capacitance” refers to the capacitance of a switch in its open or off state.

For the above reason, the present disclosure provides a switch circuit that can reduce the degradation of the transmission characteristics of multiple signal paths with different quantities of switches.

A switch circuit according to an aspect of the present disclosure includes a common terminal, a first selection terminal, a second selection terminal, and a third selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the common terminal and a second node; a fifth switch configured to connect and disconnect a fifth signal path between the second node and the third selection terminal; and a first inductor connected between the first node and a ground and is connected between the second node and the ground. Each of the quantity of switches on the second signal path and the third signal path and the quantity of switches on the fourth signal path and the fifth signal path is greater than the quantity of switches on the first signal path.

A switch circuit according to an aspect of the present disclosure includes a common terminal, a first selection terminal, and a second selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the common terminal and the first node; and a first inductor connected between the first node and a ground. Each of the quantity of switches on the second signal path and the third signal path and the quantity of switches on the fourth signal path and the third signal path is greater than the quantity of switches on the first signal path.

A switch circuit according to an aspect of the present disclosure includes a common terminal, a first selection terminal, a second selection terminal, and a third selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the first node and the third selection terminal; and a first inductor connected between the first node and a ground. Each of the quantity of switches on the second signal path and the third signal path and the quantity of switches on the second signal path and the fourth signal path is greater than the quantity of switches on the first signal path.

The present disclosure makes it possible to reduce the degradation of the transmission characteristics of multiple signal paths with different quantities of switches.

### BRIEF DESCRIPTION OF THE SEVERAL VIEWS OF THE DRAWINGS

FIG. 1 is a circuit diagram of a communication apparatus according to a first embodiment;

FIG. 2 is a Smith chart showing the input impedance and the output impedance of each of switch circuits according to the first embodiment and a comparative example;

FIG. 3 is a graph showing the insertion loss of each of the switch circuits according to the first embodiment and the comparative example;

FIG. 4 is a diagram illustrating a first mode of a radio frequency circuit according to the first embodiment;

FIG. 5 is a diagram illustrating a second mode of the radio frequency circuit according to the first embodiment;

FIG. 6 is a diagram illustrating a third mode of the radio frequency circuit according to the first embodiment;

FIG. 7 is a diagram illustrating a fourth mode of the radio frequency circuit according to the first embodiment;

FIG. 8 is a circuit diagram of a communication apparatus according to a variation of the first embodiment;

FIG. 9 is a circuit diagram of a communication apparatus according to a second embodiment;

FIG. 10 is a diagram illustrating a first mode of the radio frequency circuit according to the second embodiment;

FIG. 11 is a diagram illustrating a second mode of the radio frequency circuit according to the second embodiment;

FIG. 12 is a circuit diagram of a communication apparatus according to a variation of the second embodiment;

FIG. 13 is a circuit diagram of a communication apparatus according to a third embodiment;

FIG. 14 is a diagram illustrating a first mode of the radio frequency circuit according to the third embodiment;

FIG. 15 is a diagram illustrating a second mode of the radio frequency circuit according to the third embodiment;

FIG. 16 is a circuit diagram of a communication apparatus according to a variation of the third embodiment; and

FIG. 17 is a circuit diagram of a communication apparatus according to a fourth embodiment.

### DETAILED DESCRIPTION OF THE DISCLOSURE

Embodiments of the present disclosure are described below with reference to the drawings. Each of the embodiments described below represents a general or specific example. Values, shapes, materials, components, and layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. That is, components in each of the drawings are not necessarily illustrated accurately; and the shapes, positional relationships, and ratios of the components may differ from the actual shapes, positional relationships, and ratios. The same reference quantity is assigned to substantially the same components in the drawings, and repeated descriptions of those components may be omitted or simplified.

In the descriptions below, “connected” not only indicates that circuit elements are directly connected to each other using a connection terminal and/or a wire conductor but also indicates that the circuit elements are electrically connected to each other via another circuit element. Also, “C is connected between A and B” indicates that one end of C is connected to A, the other end of C is connected to B, and C is disposed in series in a path connecting A to B. “Path between A and B” indicates a path formed by a conductor that electrically connects A to B. Also, “directly connected” indicates that a circuit element is directly connected to a component using a connection terminal and/or a wire conductor without another circuit element interposed therebetween.

“Terminal” indicates a point at which a conductor in a circuit element ends. When the impedance of a conductor between circuit elements is sufficiently low, a terminal may be interpreted not only as a specific single point but also as any point on the conductor between the circuit elements or the entire conductor.

“Node” indicates a region between circuit elements. When the impedance of a conductor between circuit elements is sufficiently low, a node can be interpreted not only as a specific single point but also as any point on the conductor between the circuit elements or the entire conductor.

“Quantity of switches on signal path” indicates the quantity of switches that are disposed in series on a signal path. The switches, which are disposed in series, connect the signal path in the closed state and disconnect the signal path in the open state.

Terms such as “parallel” and “perpendicular” indicating relationships between elements, terms such as “linear” indicating shapes of elements, and numerical ranges do not only indicate their exact meanings but may also indicate substantially equivalent ranges that vary by, for example, about a few percent.

### First Embodiment

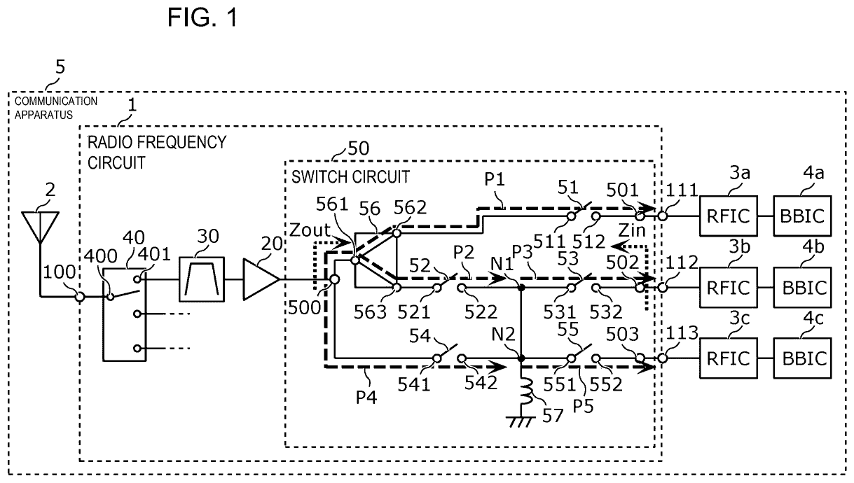

Circuit configurations of a communication apparatus 5, a radio frequency circuit 1, and a switch circuit 50 according to a first embodiment are described with reference to FIG. 1. FIG. 1 is a circuit diagram of the communication apparatus 5 according to the present embodiment. In FIG. 1, the dashed arrows represent signal paths.

FIG. 1 is an exemplary circuit diagram, and the communication apparatus 5, the radio frequency circuit 1, and the switch circuit 50 may be implemented by using any of various circuit implementations and circuit technologies. Therefore, the descriptions of the communication apparatus 5, the radio frequency circuit 1, and the switch circuit 50 provided below should not be interpreted restrictively.

### 1.1. Circuit Configuration of Communication Apparatus 5

The communication apparatus 5 according to the present embodiment can be used to provide wireless connection. For example, the communication apparatus 5 can be used for UEs in a cellular network, such as a mobile phone, a smartphone, a tablet computer, and a wearable device. As another example, the communication apparatus 5 may be used to provide wireless connection for Internet of Things (IoT), sensor devices, medical/healthcare devices, vehicles, unmanned aerial vehicles (UAV) (commonly known as drones), and automated guided vehicles (AGV). As still another example, the communication apparatus 5 may be used to provide wireless connection at wireless access points or wireless hotspots.

The communication apparatus 5 includes the radio frequency circuit 1, an antenna 2, radio frequency integrated circuits (RFICs) 3a, 3b, and 3c, and baseband integrated circuits (BBICs) 4a, 4b, and 4c.

The radio frequency circuit 1 is connected between the antenna 2 and the RFICs 3a, 3b, and 3c. The radio frequency circuit 1 can transmit radio frequency signals between the antenna 2 and the RFICs 3a, 3b, and 3c. The details of the circuit configuration of the radio frequency circuit 1 are described later.

The antenna 2 is connected to the radio frequency circuit 1. The antenna 2 can receive a radio frequency signal from the radio frequency circuit 1 and transmit the radio frequency signal to the outside of the communication apparatus 5. Also, the antenna 2 can receive a radio frequency signal from the outside of the communication apparatus 5 and supply the radio frequency signal to the radio frequency circuit 1. Here, the antenna 2 is not necessarily included in the communication apparatus 5. Also, the communication apparatus 5 may include one or more antennas in addition to the antenna 2.

The RFICs 3a, 3b, and 3c are examples of signal processing circuits for processing radio frequency signals. Specifically, the RFICs 3a, 3b, and 3c can perform signal processing, such as down-converting, on radio-frequency reception signals inputted via reception paths of the radio frequency circuit 1 and output reception signals generated by the signal processing to the BBICs 4a, 4b, and 4c, respectively. Also, the RFICs 3a, 3b, and 3c may perform signal processing, such as up-converting, on transmission signals inputted from the corresponding BBICs 4a, 4b, and 4c and output radio-frequency transmission signals generated by the signal processing to the radio frequency circuit 1. Also, each of the RFICs 3a, 3b, and 3c may include a control unit that controls, for example, switches and a power amplifier included in the radio frequency circuit 1. Here, some or all of the functions of the control units of the RFICs 3a, 3b, and 3c may be provided outside of the RFICs 3a, 3b, and 3c and may be included in, for example, the BBICs 4a, 4b, and 4c or the radio frequency circuit 1. Furthermore, any combination of the RFICs 3a, 3b, and 3c may be integrated into one circuit.

In the present embodiment, the RFICs 3a, 3b, and 3c are signal processing circuits for processing different system signals. For example, the RFIC 3a may be a signal processing circuit for processing cellular network signals. For example, the RFIC 3b may be a signal processing circuit for processing wireless local area network (WLAN) signals. Also, for example, the RFIC 3c may be a signal processing circuit for processing ultra-wide band (UWB) signals.

The BBICs 4a, 4b, and 4c are baseband signal processing circuits that process signals using a frequency band lower than that of radio frequency signals transmitted by the radio frequency circuit 1. Signals processed by the BBICs 4a, 4b, and 4c include, for example, image signals for image display and/or voice signals used for calls via a speaker. Some or all of the BBIC 4a, 4b, and 4c are not necessarily included in the communication apparatus 5. Also, any combination of the BBIC 4a, 4b, and 4c may be integrated into one circuit. Furthermore, all of the RFICs 3a, 3b, and 3c and the BBICs 4a, 4b, and 4c may be integrated into a single integrated circuit.

In the present embodiment, the BBICs 4a, 4b, and 4c are signal processing circuits for processing different system signals. For example, the BBIC 4a may be a signal processing circuit for processing cellular network signals. For example, the BBIC 4b may be a signal processing circuit for processing WLAN signals. Also, for example, the BBIC 4c may be a signal processing circuit for processing UWB signals.

### 1.2. Circuit Configuration of Radio Frequency Circuit 1

The radio frequency circuit 1 includes a low-noise amplifier 20, a filter 30, switch circuits 40 and 50, an antenna connection terminal 100, and radio frequency output terminals 111, 112, and 113.

The antenna connection terminal 100 is an external connection terminal of the radio frequency circuit 1. The antenna connection terminal 100 is connected to the antenna 2 outside of the radio frequency circuit 1 and is connected to the switch circuit 40 inside of the radio frequency circuit 1.

The radio frequency output terminals 111, 112, and 113 are external connection terminals of the radio frequency circuit 1. The radio frequency output terminals 111, 112, and 113 are connected, respectively, to the RFICs 3a, 3b, and 3c outside of the radio frequency circuit 1 and are connected to the switch circuit 50 inside of the radio frequency circuit 1.

The low-noise amplifier 20 is connected between the filter 30 and the switch circuit 50. Specifically, the input end of the low-noise amplifier 20 is connected to the filter 30, and the output end of the low-noise amplifier 20 is connected to a common terminal 500 of the switch circuit 50. The low-noise amplifier 20 can amplify a reception signal using power supplied from a power supply (not shown).

The low-noise amplifier 20 can be implemented by field-effect transistors (FETs) and can be manufactured using semiconductor materials. Examples of semiconductor materials include silicon single crystal (Si), gallium nitride (GaN), and silicon carbide (SiC). The amplification transistors used for the low-noise amplifier 20 are not limited to FETs. For example, some or all of the amplification transistors constituting the low-noise amplifier 20 may be bipolar transistors.

The filter 30 is a band pass filter having a pass band that includes a reception band of a predetermined band. The filter 30 can pass reception signals in the predetermined band and attenuate transmission signals in the predetermined band and signals in other bands.

The predetermined band is a frequency band for a communication system constructed using a radio access technology (RAT) and is predefined by a standardization organization (e.g., the Third Generation Partnership Project (3GPP, registered trademark) or the Institute of Electrical and Electronics Engineers (IEEE)). Examples of communication systems include a 5th Generation New Radio (5G NR) system, a Long Term Evolution (LTE) system, and a Wireless Local Area Network (WLAN) system.

The filter 30 is connected between the switch circuit 40 and the low-noise amplifier 20. Specifically, a first end of the filter 30 is connected to a selection terminal 401 of the switch circuit 40, and a second end of the filter 30 is connected to the input end of the low-noise amplifier 20.

As a non-limiting example, the filter 30 may be implemented by a surface acoustic wave (SAW) filter, a bulk acoustic wave (BAW) filter, an LC filter, a dielectric filter, or any combination of these filters.

The switch circuit 40 is connected between the antenna connection terminal 100 and the filter 30. The switch circuit 40 includes a common terminal 400 and a selection terminal 401. The common terminal 400 is connected to the antenna connection terminal 100. The selection terminal 401 is connected to the filter 30.

With this connection configuration, the switch circuit 40 can connect and disconnect the common terminal 400 and the selection terminal 401 to and from each other based on control signals from, for example, the RFIC 3a, 3b, or 3c.

The switch circuit 40 may further include one or more other common terminals and/or one or more other selection terminals. In this case, the one or more other common terminals may be connected to one or more other antenna connection terminals, and the one or more other selection terminals may be connected to one or more other filters.

### 1.3. Circuit Configuration of Switch Circuit 50

The switch circuit 50 is connected between the low-noise amplifier 20 and the radio frequency output terminals 111, 112, and 113. The switch circuit 50 includes a common terminal 500, selection terminals 501, 502, and 503, switches 51, 52, 53, 54, and 55, a splitter 56, and an inductor 57.

The common terminal 500 is an external connection terminal of the switch circuit 50. The common terminal 500 is connected to the output end of the low-noise amplifier 20 outside of the switch circuit 50 and is connected to the splitter 56 and the switch 54 inside of the switch circuit 50.

The selection terminal 501 is an example of a first selection terminal and is an external connection terminal of the switch circuit 50. The selection terminal 501 is connected to the radio frequency output terminal 111 outside of the switch circuit 50 and is connected to a terminal 512 of the switch 51 inside of the switch circuit 50.

The selection terminal 502 is an example of a second selection terminal and is an external connection terminal of the switch circuit 50. The selection terminal 502 is connected to the radio frequency output terminal 112 outside of the switch circuit 50 and is connected to a terminal 532 of the switch 53 inside of the switch circuit 50.

The selection terminal 503 is an example of a third selection terminal and is an external connection terminal of the switch circuit 50. The selection terminal 503 is connected to the radio frequency output terminal 113 outside of the switch circuit 50 and is connected to a terminal 552 of the switch 55 inside of the switch circuit 50.

The switch 51 is an example of a first switch and is connected between the common terminal 500 and the selection terminal 501. Specifically, the switch 51 includes a terminal 511 connected to an output terminal 562 of the splitter 56 and the terminal 512 connected to the selection terminal 501.

With this configuration, the switch 51 can connect and disconnect the terminals 511 and 512 to and from each other based on control signals from, for example, the RFIC 3a and can thereby connect and disconnect a signal path P1 between the common terminal 500 and the selection terminal 501.

The signal path P1 is an example of a first signal path and connects the common terminal 500 to the selection terminal 501. Specifically, the signal path P1 extends from the common terminal 500, via the splitter 56 and the switch 51, to the selection terminal 501.

The switch 52 is an example of a second switch and is connected between the common terminal 500 and a node N1. Specifically, the switch 52 includes a terminal 521 connected to an output terminal 563 of the splitter 56 and a terminal 522 connected to the node N1. In the present embodiment, the terminal 522 of the switch 52 is directly connected to a terminal 531 of the switch 53.

With this configuration, the switch 52 can connect and disconnect the terminals 521 and 522 to and from each other based on control signals from, for example, the RFIC 3b and/or the RFIC 3c and can thereby connect and disconnect a signal path P2.

The signal path P2 is an example of a second signal path and connects the common terminal 500 to the node N1. Specifically, the signal path P2 extends from the common terminal 500, via the splitter 56 and the switch 52, to the node N1.

The node N1 is an example of a first node and is a region on signal paths P2 and P3 to which the inductor 57 is connected. In other words, the node N1 is a region on a path connecting the switches 52 and 53 to each other.

The switch 53 is an example of a third switch and is connected between the node N1 and the selection terminal 502. Specifically, the switch 53 includes the terminal 531 connected to the node N1 and the terminal 532 connected to the selection terminal 502. In the present embodiment, the terminal 531 of the switch 53 is directly connected to the terminal 522 of the switch 52 and a terminal 542 of the switch 54.

With this configuration, the switch 53 can connect and disconnect the terminals 531 and 532 to and from each other based on control signals from, for example, the RFIC 3b and can thereby connect and disconnect a signal path P3.

The signal path P3 is an example of a third signal path and connects the node N1 to the selection terminal 502. Specifically, the signal path P3 extends from the node N1, via the switch 53, to the selection terminal 502.

The switch 54 is an example of a fourth switch and is connected between the common terminal 500 and a node N2. Specifically, the switch 54 includes a terminal 541 connected to the common terminal 500 and the terminal 542 connected to the node N2. In the present embodiment, the terminal 542 of the switch 54 is directly connected to a terminal 551 of the switch 55.

With this configuration, the switch 54 can connect and disconnect the terminals 541 and 542 to and from each other based on control signals from, for example, the RFIC 3b and/or the RFIC 3c and can thereby connect and disconnect a signal path P4.

The signal path P4 is an example of a fourth signal path and connects the common terminal 500 to the node N2. Specifically, the signal path P4 extends from the common terminal 500, via the switch 54, to the node N2.

The node N2 is an example of a second node and is a region on the signal paths P4 and P5 to which the inductor 57 is connected. In other words, the node N2 is a region on a path connecting the switches 54 and 55 to each other.

The switch 55 is an example of a fifth switch and is connected between the node N2 and the selection terminal 503. Specifically, the switch 55 includes the terminal 551 connected to the node N2 and the terminal 552 connected to the selection terminal 503. In the present embodiment, the terminal 551 of the switch 55 is directly connected to the terminal 542 of the switch 54.

With this configuration, the switch 55 can connect and disconnect the terminals 551 and 552 to and from each other based on control signals from, for example, the RFIC 3c and can thereby connect and disconnect a signal path P5.

The signal path P5 is an example of a fifth signal path and connects the node N2 to the selection terminal 503. Specifically, the signal path P5 extends from the node N2, via the switch 55, to the selection terminal 503.

Each of the switches 51 to 55 is implemented by, for example, a single-pole single-throw (SPST) switch circuit. For example, each of the switches 51 to 55 includes multiple series-connected FETs. Alternatively, each of the switches 51 to 55 may include only one FET.

The splitter 56 includes an input terminal 561 and output terminals 562 and 563. The input terminal 561 is connected to the common terminal 500. The output terminal 562 is an example of a first output terminal and is connected to the selection terminal 501 via the switch 51. The output terminal 563 is an example of a second output terminal and is connected to the nodes N1 and N2 via the switch 52. The splitter 56 can distribute a radio frequency signal supplied to the input terminal 561 to the signal paths P1 and P2. As a non-limiting example, the splitter 56 may be implemented by a Wilkinson divider or a diplexer. The splitter 56 is not necessarily included in the switch circuit 50.

The inductor 57 is an example of a first inductor, is connected between the node N1 and the ground, and is also connected between the node N2 and the ground. Specifically, a first end of the inductor 57 is connected to the nodes N1 and N2, and a second end of the inductor 57 is connected to the ground.

In the switch circuit 50 as described above, each of the quantity of switches on the signal paths P2 and P3 (two in the present embodiment) and the quantity of switches on the signal paths P4 and P5 (two in the present embodiment) is greater than the quantity of switches on the signal path P1 (one in the present embodiment). With this configuration, each of the parasitic capacitance (hereafter referred to as off-capacitance) generated when the switches on the signal paths P2 and P3 are opened and the off-capacitance of the switches on the signal paths P4 and P5 is greater than the off-capacitance of the switch on the signal path P1.

Also, the quantity of switches on the signal paths P2 and P3 (two in the present embodiment) is equal to the quantity of switches on the signal paths P4 and P5 (two in the present embodiment). Accordingly, the off-capacitance of the switches on the signal paths P2 and P3 is equal to the off-capacitance of the switches on the signal paths P4 and P5.

The switch circuit 50 can be implemented in a single integrated circuit. That is, the switches 51, 52, 53, 54, and 55, the splitter 56, and the inductor 57 may be included in a single integrated circuit. The inductor 57 is not necessarily included in the integrated circuit. In this case, the inductor 57 may be implemented by wires on and/or in a substrate. Also, the inductor 57 may be implemented by a chip inductor (surface mount device, SMD).

### 1.4. Impedance of Switch Circuit 50

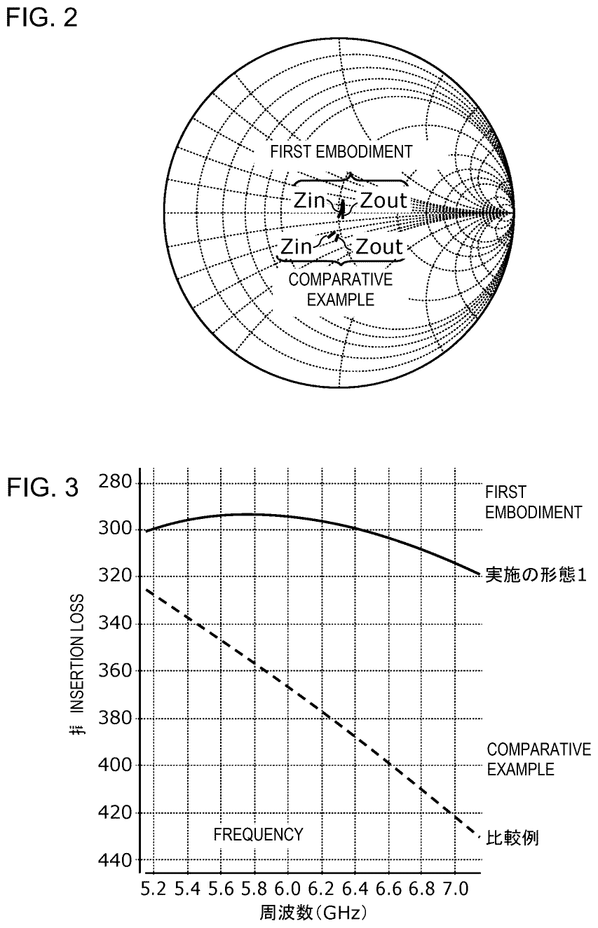

Referring to FIGS. 2 and 3, the impedance of the switch circuit 50 of the present embodiment configured as described above is described through comparison with a switch circuit according to a comparative example. The switch circuit according to the comparative example is obtained by removing the inductor 57 and the path connecting the nodes N1 and N2 to the ground from the switch circuit 50 of the present embodiment.

FIG. 2 is a Smith chart showing input impedance Zin and output impedance Zout of each of the switch circuits 50 according to the present embodiment and the comparative example. FIG. 3 is a graph showing the insertion loss of each of the switch circuits 50 according to the present embodiment and the comparative example.

The input impedance Zin is the impedance that is observed when the common terminal 500 is seen from the selection terminal 502 in a state in which the switches 52 and 53 are closed and the switches 51, 54, and 55 are also closed. The output impedance Zout is the impedance that is observed when the selection terminal 502 is seen from the common terminal 500 in a state in which the switches 52 and 53 are closed and the switches 51, 54, and 55 are also closed.

As shown in FIG. 2, the switch circuit 50 according to the present embodiment can make the input impedance Zin and the output impedance Zout closer to reference impedance (for example, 50 ohms) than the input impedance Zin and the output impedance Zout of the switch circuit of the comparative example. This is because the inductor 57 can cause the impedance, which has shifted toward the capacitive side due to the difference between the off-capacitance of the switch 51 on the signal path P1 and the off-capacitance of the switches 54 and 55 on the signal paths P4 and P5, to shift toward the inductive side.

Accordingly, compared with the switch circuit of the comparative example, the switch circuit 50 of the present embodiment can reduce the loss resulting from impedance mismatching and can reduce the insertion loss caused by the switch circuit 50 as shown in FIG. 3.

### 1.5. Multiple Communication Modes

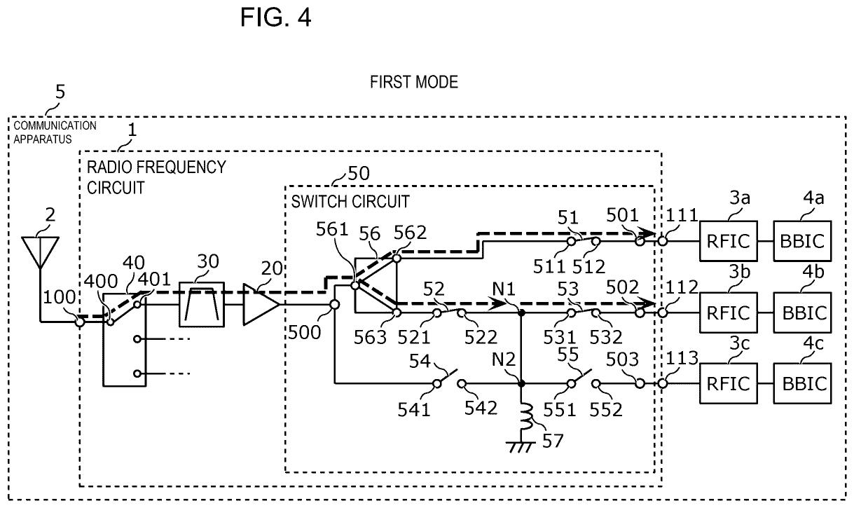

Next, multiple communication modes of the radio frequency circuit 1 are described with reference to FIGS. 4 to 7. In FIGS. 4 to 7, the dashed arrows represent reception paths of radio frequency signals in the corresponding communication modes.

### 1.5.1. First Mode

First, a first mode included in the multiple communication modes of the radio frequency circuit 1 is described with reference to FIG. 4. FIG. 4 is a diagram illustrating the first mode of the radio frequency circuit 1 of the present embodiment.

The first mode is a communication mode for receiving a radio frequency signal (for example, a cellular network signal) to be processed by the RFIC 3a and a radio frequency signal (for example, a WLAN signal) to be processed by the RFIC 3b.

In the first mode, the switch circuit 40 connects the common terminal 400 to the selection terminal 401. Also, the switch circuit 50 connects the common terminal 500 to the selection terminals 501 and 502 but not to the selection terminal 503. Specifically, the switch circuit 50 closes the switches 51, 52, and 53 and opens the switches 54 and 55.

As a result, two reception signals are transmitted from the antenna 2, via the antenna connection terminal 100, the switch circuit 40, the filter 30, the low-noise amplifier 20, the switch circuit 50, and the radio frequency output terminals 111 and 112, to the RFICs 3a and 3b. In the switch circuit 50, one of the two reception signals is transmitted from the common terminal 500, via the splitter 56 and the switch 51, to the selection terminal 501; and the other one of the two reception signals is transmitted from the common terminal 500, via the splitter 56 and the switches 52 and 53, to the selection terminal 502.

### 1.5.2. Second Mode

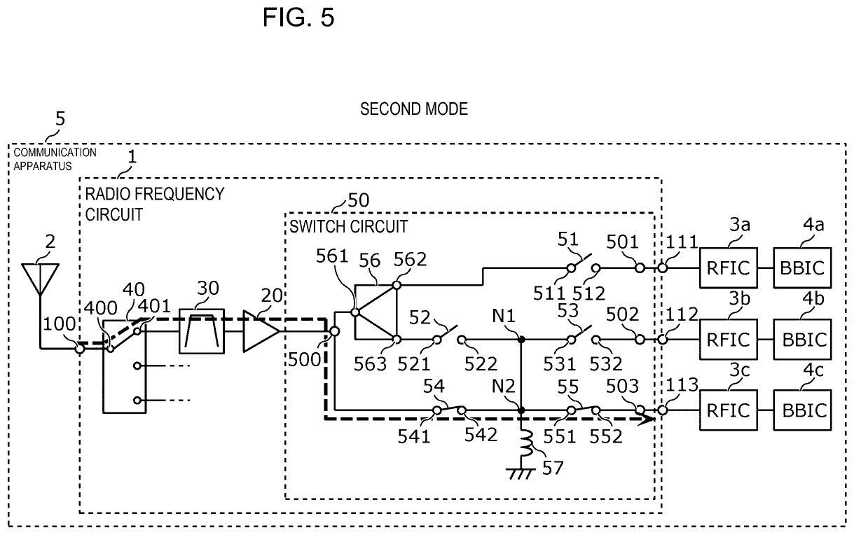

Next, a second mode included in the multiple communication modes of the radio frequency circuit 1 is described with reference to FIG. 5. FIG. 5 is a diagram illustrating the second mode of the radio frequency circuit 1 of the present embodiment.

The second mode is a communication mode for receiving a radio frequency signal (for example, an UWB signal) to be processed by the RFIC 3c.

In the second mode, the switch circuit 40 connects the common terminal 400 to the selection terminal 401. Also, the switch circuit 50 connects the common terminal 500 to the selection terminal 503 but not to the selection terminals 501 and 502. Specifically, the switch circuit 50 closes the switches 54 and 55 and opens the switches 51, 52, and 53.

As a result, a reception signal is transmitted from the antenna 2, via the antenna connection terminal 100, the switch circuit 40, the filter 30, the low-noise amplifier 20, the switch circuit 50, and the radio frequency output terminal 113, to the RFIC 3c. In the switch circuit 50, the reception signal is transmitted from the common terminal 500, via the switches 54 and 55, to the selection terminal 503.

### 1.5.3. Third Mode

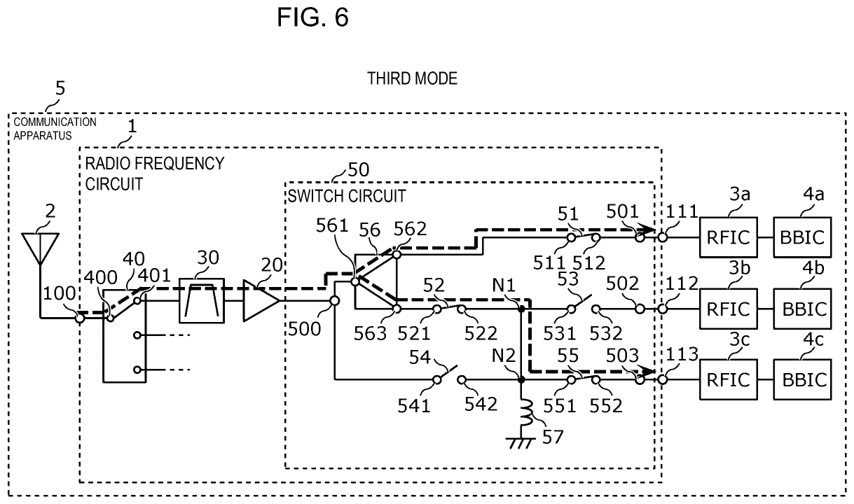

Next, a third mode included in the multiple communication modes of the radio frequency circuit 1 is described with reference to FIG. 6. FIG. 6 is a diagram illustrating the third mode of the radio frequency circuit 1 of the present embodiment.

The third mode is a communication mode for receiving a radio frequency signal (for example, a cellular network signal) to be processed by the RFIC 3a and a radio frequency signal (for example, a UWB signal) to be processed by the RFIC 3c.

In the third mode, the switch circuit 40 connects the common terminal 400 to the selection terminal 401. Also, the switch circuit 50 connects the common terminal 500 to the selection terminals 501 and 503 but not to the selection terminal 502. Specifically, the switch circuit 50 closes the switches 51, 52, and 55 and opens the switches 53 and 54.

As a result, two reception signals are transmitted from the antenna 2, via the antenna connection terminal 100, the switch circuit 40, the filter 30, the low-noise amplifier 20, the switch circuit 50, and the radio frequency output terminals 111 and 113, to the RFICs 3a and 3c. In the switch circuit 50, one of the two reception signals is transmitted from the common terminal 500, via the splitter 56 and the switch 51, to the selection terminal 501; and the other one of the two reception signals is transmitted from the common terminal 500, via the splitter 56 and the switches 52 and 55, to the selection terminal 503.

### 1.5.4. Fourth Mode

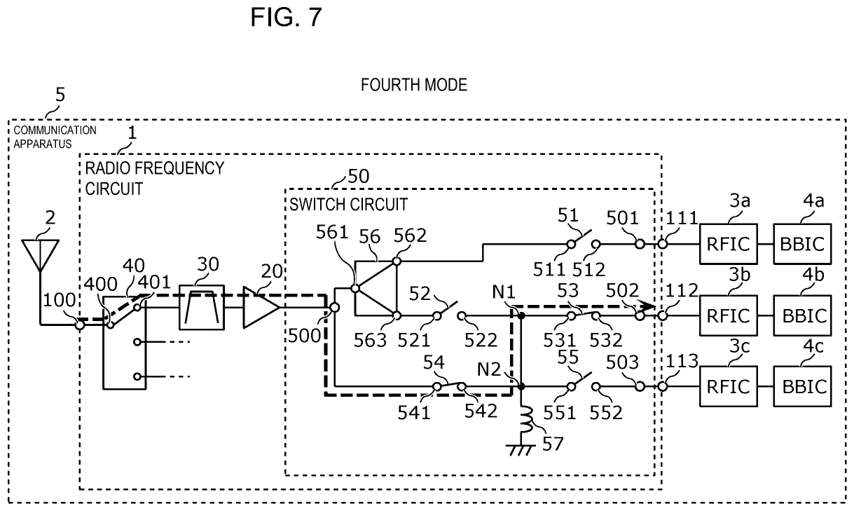

Next, a fourth mode included in the multiple communication modes of the radio frequency circuit 1 is described with reference to FIG. 7. FIG. 7 is a diagram illustrating the fourth mode of the radio frequency circuit 1 of the present embodiment.

The fourth mode is a communication mode for receiving a radio frequency signal (for example, a WLAN signal) to be processed by the RFIC 3b.

In the fourth mode, the switch circuit 40 connects the common terminal 400 to the selection terminal 401. Also, the switch circuit 50 connects the common terminal 500 to the selection terminal 502 but not to the selection terminals 501 and 503. Specifically, the switch circuit 50 closes the switches 53 and 54 and opens the switches 51, 52, and 55.

As a result, the reception signal is transmitted from the antenna 2, via the antenna connection terminal 100, the switch circuit 40, the filter 30, the low-noise amplifier 20, the switch circuit 50, and the radio frequency output terminal 112, to the RFIC 3b. In the switch circuit 50, the reception signal is transmitted from the common terminal 500, via the switches 54 and 53, to the selection terminal 502.

The multiple communication modes of the radio frequency circuit 1 are not limited to the first to fourth modes. For example, the multiple communication modes of the radio frequency circuit 1 may include communication modes that are different from the first to fourth modes.

### 1.6. Summary

As described above, the switch circuit 50 according to the present embodiment includes the common terminal 500; the selection terminals 501, 502, and 503; the switch 51 configured to connect and disconnect the signal path P1 between the common terminal 500 and the selection terminal 501; the switch 52 configured to connect and disconnect the signal path P2 between the common terminal 500 and the node N1; the switch 53 configured to connect and disconnect the signal path P3 between the node N1 and the selection terminal 502; the switch 54 configured to connect and disconnect the signal path P4 between the common terminal 500 and the node N2; the switch 55 configured to connect and disconnect the signal path P5 between the node N2 and the selection terminal 503; and the inductor 57 connected between the node N1 and the ground and also connected between node N2 and the ground. Each of the quantity of switches on the signal paths P2 and P3 and the quantity of switches on the signal paths P4 and P5 is greater than the quantity of switches on the signal path P1.

With this configuration, because the inductor 57 is connected to the signal paths P2 and P3 and the signal paths P4 and P5, which have a greater quantity of switches, it is possible to reduce impedance mismatching caused by the difference in the off-capacitance between these signal paths and the signal path P1, which has a smaller quantity of switches. That is, the above configuration makes it possible to reduce the degradation of the transmission characteristics of multiple signal paths with different quantities of switches. Also, because the common inductor 57 is connected to the signal paths P2 and P3 and the signal paths P4 and P5, it is possible to reduce the quantity of inductors compared to a case in which separate inductors are connected to the signal paths P2 and P3 and to the signal paths P4 and P5. That is, the above configuration makes it possible to reduce the size of the switch circuit 50.

Also, for example, in the switch circuit 50 of the present embodiment, the quantity of switches on the signal paths P2 and P3 may be equal to the quantity of switches on the signal paths P4 and P5.

This in turn makes it possible to reduce the difference between the off-capacitance of the switches on the signal paths P2 and P3 and the off-capacitance of the switches on the signal paths P4 and P5 and thereby makes it possible to effectively adjust the impedance using the inductor 57.

Also, for example, in the switch circuit 50 of the present embodiment, the switch 52 may be directly connected to the switch 53, and the switch 54 may be directly connected to the switch 55.

With this configuration, the inductor 57 is connected between the ground and the node N1 on the path directly connecting the switch 52 to the switch 53 and between the ground and the node N2 on the path directly connecting the switch 54 to the switch 55. This makes it possible to effectively reduce impedance mismatching caused by the off-capacitance of the switches 52 and 53 and the off-capacitance of the switches 54 and 55.

Also, for example, in the switch circuit 50 of the present embodiment, in the first mode, the switches 51, 52, and 53 may be closed, and the switches 54 and 55 may be opened; in the second mode, the switches 54 and 55 may be closed, and the switches 51, 52, and 53 may be opened; in the third mode, the switches 51, 52, and 55 may be closed, and the switches 53 and 54 may be opened; and in the fourth mode, the switches 53 and 54 may be opened, and the switches 51, 52, and 55 may be closed.

With this configuration, the common terminal 500 can be connected to the selection terminals 501 and 502 in the first mode, the common terminal 500 can be connected to the selection terminal 503 in the second mode, the common terminal 500 can be connected to the selection terminals 501 and 503 in the third mode, and the common terminal 500 can be connected to the selection terminal 502 in the fourth mode. The inductor 57 makes it possible to reduce the impedance mismatching caused by the difference in the quantity of switches on the signal paths in the first to fourth modes.

Also, for example, the switch circuit 50 according to the present embodiment may further include the splitter 56 that includes the input terminal 561 connected to the common terminal 500, the output terminal 562 connected to the selection terminal 501 via the switch 51, and the output terminal 563 connected to the nodes N1 and N2 via the switch 52.

This makes it possible to distribute an input signal inputted to the common terminal 500 to two selection terminals.

Also, for example, in the switch circuit 50 of the present embodiment, the switches 51, 52, 53, 54, and 55 and the inductor 57 may be included in a single integrated circuit.

This makes it possible to reduce the size of the switch circuit 50.

### Variation of First Embodiment

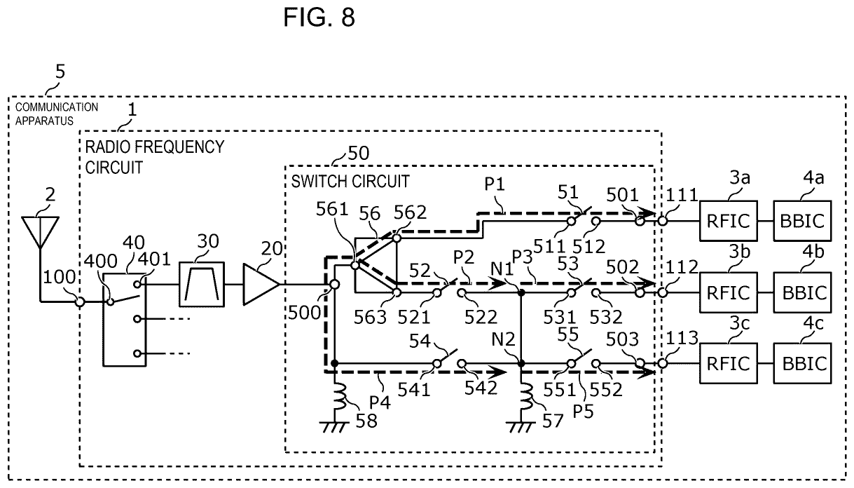

In the circuit configurations of the communication apparatus 5, the radio frequency circuit 1, and the switch circuit 50 according to the first embodiment, additional circuit elements and wires may be inserted in paths connecting circuit elements and signal paths illustrated in the diagrams. For example, as illustrated in FIG. 8, a switch circuit 50 according to a variation of the first embodiment may further include an inductor 58.

The inductor 58 is an example of a second inductor and is connected between the common terminal 500 and the ground. Specifically, a first end of the inductor 58 is connected to the common terminal 500, and a second end of the inductor 58 is connected to the ground.

Thus, the switch circuit 50 according to the present variation further includes the inductor 58 connected between the common terminal 500 and the ground.

This makes it possible to further adjust the impedance in multiple signal paths with different quantities of switches and thereby makes it possible to further reduce the degradation of transmission characteristics.

### Second Embodiment

Next, a second embodiment is described. The present embodiment differs primarily from the first embodiment in that the quantity of radio frequency output terminals of the radio frequency circuit is different from that in the first embodiment and, as a result, the signal path P5 is not included in the switch circuit. Below, differences between the first embodiment and the second embodiment are mainly described with reference to the drawings.

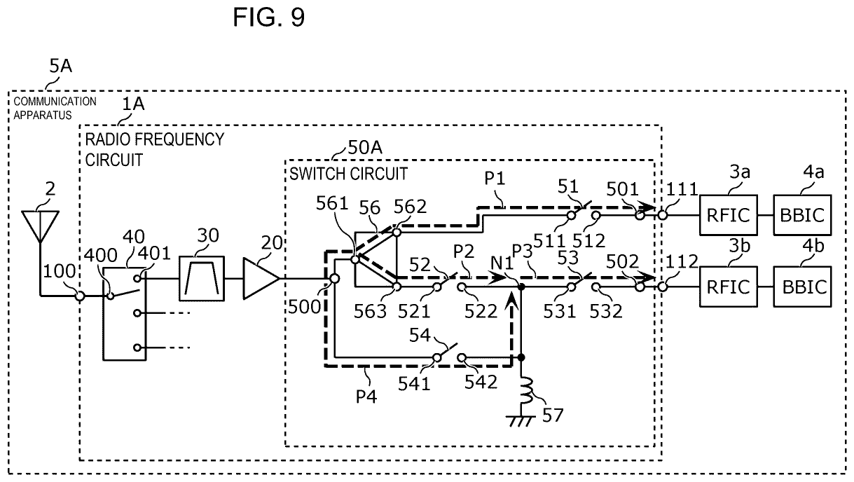

FIG. 9 is a circuit diagram of a communication apparatus 5A according to the present embodiment. In FIG. 9, the dashed arrows represent signal paths.

FIG. 9 is an exemplary circuit diagram, and the communication apparatus 5A, a radio frequency circuit 1A, and a switch circuit 50A may be implemented by using any of various circuit implementations and circuit technologies. Therefore, the descriptions of the communication apparatus 5A, the radio frequency circuit 1A, and the switch circuit 50A provided below should not be interpreted restrictively.

### 2.1. Circuit Configuration of Communication Apparatus 5A

As with the communication apparatus 5 according to the first embodiment, the communication apparatus 5A according to the present embodiment can be used to provide wireless connection. The communication apparatus 5A includes a radio frequency circuit 1A, an antenna 2, RFICs 3a and 3b, and BBICs 4a and 4b. That is, the communication apparatus 5A differs from the communication apparatus 5 according to the first embodiment in that the communication apparatus 5A includes the radio frequency circuit 1A instead of the radio frequency circuit 1 and does not include the RFIC 3c and the BBIC 4c.

### 2.2. Circuit Configuration of Radio Frequency Circuit 1A

The radio frequency circuit 1A of the present embodiment includes a low-noise amplifier 20, a filter 30, switch circuits 40 and 50A, an antenna connection terminal 100, and radio frequency output terminals 111 and 112. That is, the radio frequency circuit 1A differs from the radio frequency circuit 1 of the first embodiment in that the radio frequency circuit 1A includes the switch circuit 50A instead of the switch circuit 50 and does not include the radio frequency output terminal 113.

### 2.3. Circuit Configuration of Switch Circuit 50A

The switch circuit 50A according to the present embodiment is connected between the low-noise amplifier 20 and the radio frequency output terminals 111 and 112. The switch circuit 50A includes a common terminal 500, selection terminals 501 and 502, switches 51, 52, 53, and 54, a splitter 56, and an inductor 57.

The common terminal 500 is an external connection terminal of the switch circuit 50A. The common terminal 500 is connected to the output end of the low-noise amplifier 20 outside of the switch circuit 50A and is connected to the splitter 56 and the switch 54 inside of the switch circuit 50A.

The selection terminal 501 is an example of a first selection terminal and is an external connection terminal of the switch circuit 50A. The selection terminal 501 is connected to the radio frequency output terminal 111 outside of the switch circuit 50A and is connected to a terminal 512 of the switch 51 inside of the switch circuit 50A.

The selection terminal 502 is an example of a second selection terminal and is an external connection terminal of the switch circuit 50A. The selection terminal 502 is connected to the radio frequency output terminal 112 outside of the switch circuit 50A and is connected to a terminal 532 of the switch 53 inside of the switch circuit 50A.

The switch 51 is an example of a first switch and is connected between the common terminal 500 and the selection terminal 501. Specifically, the switch 51 includes a terminal 511 connected to an output terminal 562 of the splitter 56 and the terminal 512 connected to the selection terminal 501.

With this configuration, the switch 51 can connect and disconnect the terminals 511 and 512 to and from each other based on control signals from, for example, the RFIC 3a and can thereby connect and disconnect a signal path P1.

The signal path P1 is an example of a first signal path and connects the common terminal 500 to the selection terminal 501. Specifically, the signal path P1 extends from the common terminal 500, via the splitter 56 and the switch 51, to the selection terminal 501.

The switch 52 is an example of a second switch and is connected between the common terminal 500 and a node N1. Specifically, the switch 52 includes a terminal 521 connected to an output terminal 563 of the splitter 56 and a terminal 522 connected to the node N1. In the present embodiment, the terminal 522 of the switch 52 is directly connected to a terminal 531 of the switch 53.

With this configuration, the switch 52 can connect and disconnect the terminals 521 and 522 to and from each other based on control signals from, for example, the RFIC 3b and can thereby connect and disconnect a signal path P2.

The signal path P2 is an example of a second signal path and connects the common terminal 500 to the node N1. Specifically, the signal path P2 extends from the common terminal 500, via the splitter 56 and the switch 52, to the node N1.

The node N1 is an example of a first node and is a region on signal paths P2 and P3 to which the inductor 57 is connected. In other words, the node N1 is a region on a path connecting the switches 52 and 53 to each other.

The switch 53 is an example of a third switch and is connected between the node N1 and the selection terminal 502. Specifically, the switch 53 includes the terminal 531 connected to the node N1 and the terminal 532 connected to the selection terminal 502. In the present embodiment, the terminal 531 of the switch 53 is directly connected to the terminal 522 of the switch 52.

With this configuration, the switch 53 can connect and disconnect the terminals 531 and 532 to and from each other based on control signals from, for example, the RFIC 3b and can thereby connect and disconnect a signal path P3.

The signal path P3 is an example of a third signal path and connects the node N1 to the selection terminal 502. Specifically, the signal path P3 extends from the node N1, via the switch 53, to the selection terminal 502.

The switch 54 is an example of a fourth switch and is connected between the common terminal 500 and the node N1. Specifically, the switch 54 includes a terminal 541 connected to the common terminal 500 and a terminal 542 connected to the node N1. In the present embodiment, the terminal 542 of the switch 54 is directly connected to the terminal 531 of the switch 53.

With this configuration, the switch 54 can connect and disconnect the terminals 541 and 542 to and from each other based on control signals from, for example, the RFIC 3b and can thereby connect and disconnect a signal path P4.

The signal path P4 is an example of a fourth signal path and connects the common terminal 500 to the node N1. Specifically, the signal path P4 extends from the common terminal 500, via the switch 54, to the node N1.

Each of the switches 51 to 54 is implemented by, for example, a single-pole single-throw (SPST) switch circuit. For example, each of the switches 51 to 54 includes multiple series-connected FETs. Alternatively, each of the switches 51 to 54 may include only one FET.

The splitter 56 includes an input terminal 561 and output terminals 562 and 563. The input terminal 561 is connected to the common terminal 500. The output terminal 562 is an example of a first output terminal and is connected to the selection terminal 501 via the switch 51. The output terminal 563 is an example of a second output terminal and is connected to the node N1 via the switch 52. The splitter 56 can distribute a radio frequency signal supplied to the input terminal 561 to the signal paths P1 and P2. As a non-limiting example, the splitter 56 may be implemented by a Wilkinson divider or a diplexer. The splitter 56 is not necessarily included in the switch circuit 50A.

The inductor 57 is an example of a first inductor and is connected between the node N1 and the ground. Specifically, a first end of the inductor 57 is connected to the node N1, and a second end of the inductor 57 is connected to the ground.

In the switch circuit 50A as described above, each of the quantity of switches on the signal paths P2 and P3 (two in the present embodiment) and the quantity of switches on the signal paths P4 and P3 (two in the present embodiment) is greater than the quantity of switches on the signal path P1 (one in the present embodiment). With this configuration, each of the off-capacitance of the switches on the signal paths P2 and P3 and the off-capacitance of the switches on the signal paths P4 and P3 is greater than the off-capacitance of the switch on the signal path P1.

Also, the quantity of switches on the signal path P2 (one in the present embodiment) is equal to the quantity of switches on the signal path P4 (one in the present embodiment). Accordingly, the off-capacitance of the switches on the signal paths P2 and P3 is equal to the off-capacitance of the switches on the signal paths P4 and P3.

### 2.4. Multiple Communication Modes

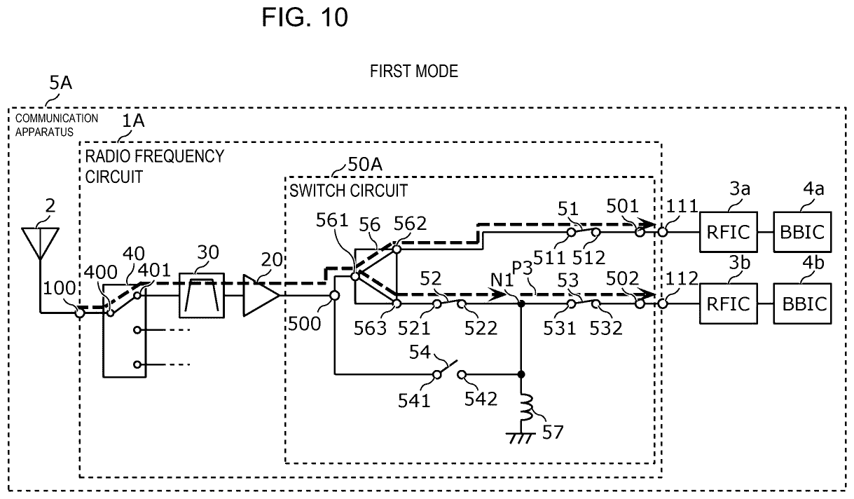

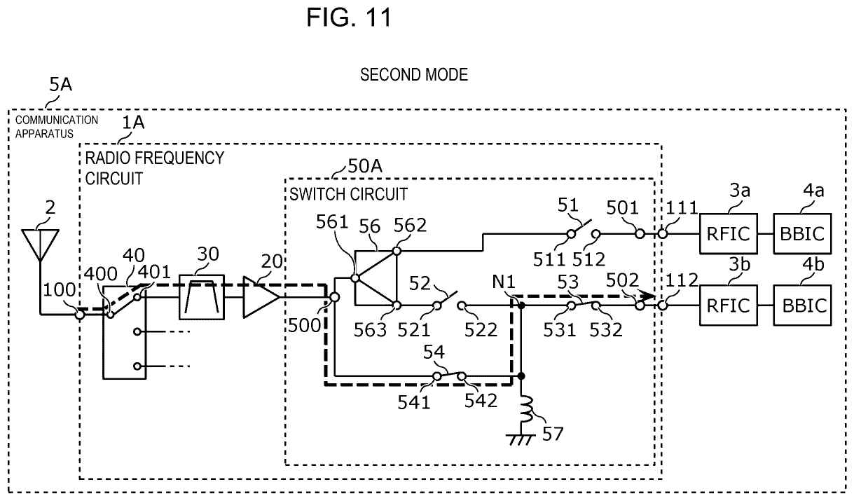

Next, multiple communication modes of the radio frequency circuit 1A are described with reference to FIGS. 10 and 11. In FIGS. 10 and 11, the dashed arrows represent reception paths of radio frequency signals in the corresponding communication modes.

### 2.4.1. First Mode

First, a first mode included in the multiple communication modes of the radio frequency circuit 1A is described with reference to FIG. 10. FIG. 10 is a diagram illustrating the first mode of the radio frequency circuit 1A of the present embodiment.

The first mode is a communication mode for receiving a radio frequency signal (for example, a cellular network signal) to be processed by the RFIC 3a and a radio frequency signal (for example, a WLAN signal) to be processed by the RFIC 3b.

In the first mode, the switch circuit 40 connects the common terminal 400 to the selection terminal 401. Also, the switch circuit 50A connects the common terminal 500 to the selection terminals 501 and 502. Specifically, the switch circuit 50A closes the switches 51, 52, and 53 and opens the switch 54.

As a result, two reception signals are transmitted from the antenna 2, via the antenna connection terminal 100, the switch circuit 40, the filter 30, the low-noise amplifier 20, the switch circuit 50A, and the radio frequency output terminals 111 and 112, to the RFICs 3a and 3b. In the switch circuit 50A, one of the two reception signals is transmitted from the common terminal 500, via the splitter 56 and the switch 51, to the selection terminal 501; and the other one of the two reception signals is transmitted from the common terminal 500, via the splitter 56 and the switches 52 and 53, to the selection terminal 502.

### 2.4.2. Second Mode

Next, a second mode included in the multiple communication modes of the radio frequency circuit 1A is described with reference to FIG. 11. FIG. 11 is a diagram illustrating the second mode of the radio frequency circuit 1A of the present embodiment.

The second mode is a communication mode for receiving a radio frequency signal (for example, a WLAN signal) to be processed by the RFIC 3b.

In the second mode, the switch circuit 40 connects the common terminal 400 to the selection terminal 401. Also, the switch circuit 50A connects the common terminal 500 to the selection terminal 502 but not to the selection terminal 501. Specifically, the switch circuit 50A closes the switches 53 and 54 and opens the switches 51 and 52.

As a result, a reception signal is transmitted from the antenna 2, via the antenna connection terminal 100, the switch circuit 40, the filter 30, the low-noise amplifier 20, the switch circuit 50A, and the radio frequency output terminal 112, to the RFIC 3b. In the switch circuit 50A, the reception signal is transmitted from the common terminal 500, via the switches 54 and 53, to the selection terminal 502.

The multiple communication modes of the radio frequency circuit 1A are not limited to the first and second modes. For example, the multiple communication modes of the radio frequency circuit 1A may include communication modes that are different from the first and second modes.

### 2.5. Summary

As described above, the switch circuit 50A of the present embodiment includes the common terminal 500; the selection terminals 501 and 502; the switch 51 configured to connect and disconnect the signal path P1 between the common terminal 500 and the selection terminal 501; the switch 52 configured to connect and disconnect the signal path P2 between the common terminal 500 and the node N1; the switch 53 configured to connect and disconnect the signal path P3 between the node N1 and the selection terminal 502; the switch 54 configured to connect and disconnect the signal path P4 between the common terminal 500 and the node N1; and the inductor 57 connected between the node N1 and the ground. Each of the quantity of switches on the signal path P2 and the signal path P3 and the quantity of switches on the signal path P4 and the signal path P3 is greater than the quantity of switches on the signal path P1.

With this configuration, because the inductor 57 is connected to the signal paths P2 and P3 and the signal paths P3 and P4, which have a greater quantity of switches, it is possible to reduce impedance mismatching caused by the difference in the off-capacitance between these signal paths and the signal path P1, which has a smaller quantity of switches. That is, the above configuration makes it possible to reduce the degradation of the transmission characteristics of multiple signal paths with different quantities of switches. Also, because the common inductor 57 is connected to the signal paths P2 and P3 and the signal paths P3 and P4, it is possible to reduce the quantity of inductors compared to a case in which separate inductors are connected to the signal paths P2 and P3 and to the signal paths P3 and P4. That is, the above configuration makes it possible to reduce the size of the switch circuit 50A.

Also, for example, in the switch circuit 50A of the present embodiment, the quantity of switches on the signal path P2 may be equal to the quantity of switches on the signal path P4.

This in turn makes it possible to reduce the difference between the off-capacitance of the switches on the signal paths P2 and P3 and the off-capacitance of the switches on the signal paths P3 and P4 and thereby makes it possible to effectively adjust the impedance using the inductor 57.

Also, for example, in the switch circuit 50A of the present embodiment, the switch 53 may be directly connected to the switches 52 and 54.

With this configuration, the inductor 57 is connected between the ground and the node N1 on the path directly connecting the switch 53 to the switches 52 and 54. This makes it possible to effectively reduce impedance mismatching caused by the off-capacitance of the switches 52 and 53 and the off-capacitance of the switches 53 and 54.

Also, for example, in the switch circuit 50A of the present embodiment, in the first mode, the switches 51, 52, and 53 may be closed, and the switch 54 may be opened; and in the second mode, the switches 53 and 54 may be closed, and the switches 51 and 52 may be opened.

With this configuration, the common terminal 500 can be connected to the selection terminals 501 and 502 in the first mode, and the common terminal 500 can be connected to the selection terminal 502 in the second mode. The inductor 57 makes it possible to reduce the impedance mismatching caused by the difference in the quantity of switches on the signal paths in the first and second modes.

Also, for example, the switch circuit 50A according to the present embodiment may further include the splitter 56 that includes the input terminal 561 connected to the common terminal 500, the output terminal 562 connected to the selection terminal 501 via the switch 51, and the output terminal 563 connected to the node N1 via the switch 52.

This makes it possible to distribute an input signal inputted to the common terminal 500 to two selection terminals.

Also, for example, in the switch circuit 50A of the present embodiment, the switches 51, 52, 53, and 54 and the inductor 57 may be included in a single integrated circuit.

This makes it possible to reduce the size of the switch circuit 50A.

### Variation of Second Embodiment

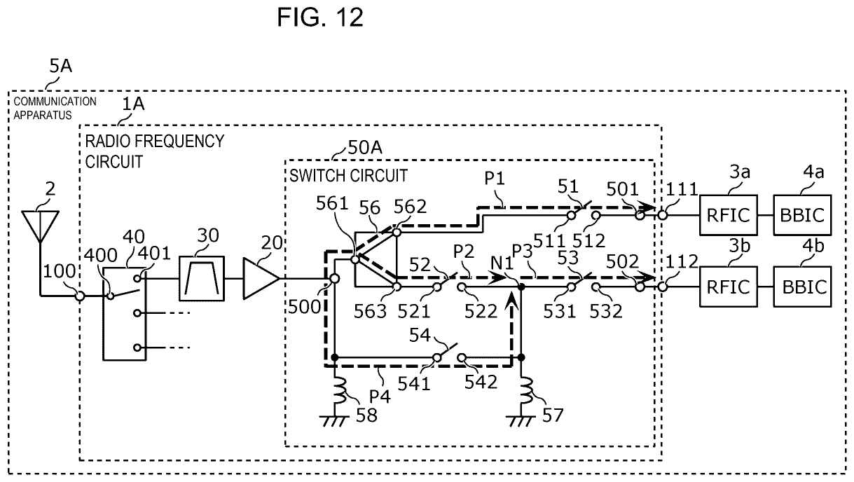

In the circuit configurations of the communication apparatus 5A, the radio frequency circuit 1A, and the switch circuit 50A according to the second embodiment, additional circuit elements and wires may be inserted in paths connecting circuit elements and signal paths illustrated in the diagrams. For example, as illustrated in FIG. 12, a switch circuit 50A according to a variation of the second embodiment may further include an inductor 58.

The inductor 58 is an example of a second inductor and is connected between the common terminal 500 and the ground. Specifically, a first end of the inductor 58 is connected to the common terminal 500, and a second end of the inductor 58 is connected to the ground.

Thus, the switch circuit 50A according to the present variation further includes the inductor 58 connected between the common terminal 500 and the ground.

This makes it possible to further adjust the impedance in multiple signal paths with different quantites of switches and thereby makes it possible to further reduce the degradation of transmission characteristics.

### Third Embodiment

Next, a third embodiment is described. The present embodiment differs primarily from the first embodiment in that the signal path P4 is not included in the switch circuit. Below, differences between the first embodiment and the third embodiment are mainly described with reference to the drawings.

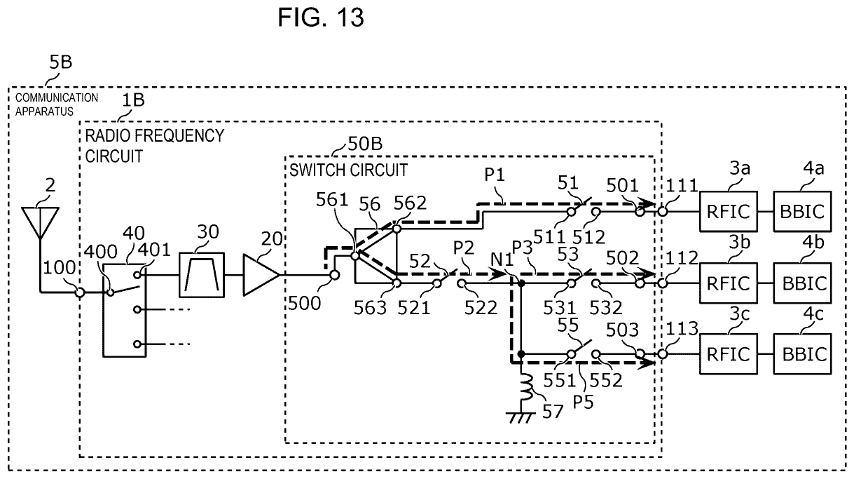

FIG. 13 is a circuit diagram of a communication apparatus 5B according to the present embodiment. In FIG. 13, the dashed arrows represent signal paths.

FIG. 13 is an exemplary circuit diagram, and the communication apparatus 5B, a radio frequency circuit 1B, and a switch circuit 50B may be implemented by using any of various circuit implementations and circuit technologies. Therefore, the descriptions of the communication apparatus 5B, the radio frequency circuit 1B, and the switch circuit 50B provided below should not be interpreted restrictively.

### 3.1. Circuit Configuration of Communication Apparatus 5B

As with the communication apparatus 5 according to the first embodiment, the communication apparatus 5B according to the present embodiment can be used to provide wireless connection. The communication apparatus 5B includes the radio frequency circuit 1B, an antenna 2, RFICs 3a, 3b, and 3c, and BBICs 4a, 4b, and 4c. That is, the communication apparatus 5B differs from the communication apparatus 5 according to the first embodiment in that the radio frequency circuit 1B is provided in place of the radio frequency circuit 1.

### 3.2. Circuit Configuration of Radio Frequency Circuit 1B

The radio frequency circuit 1B of the present embodiment includes a low-noise amplifier 20, a filter 30, switch circuits 40 and 50B, an antenna connection terminal 100, and radio frequency output terminals 111, 112, and 113. That is, the radio frequency circuit 1B differs from the radio frequency circuit 1 according to the first embodiment in that the switch circuit 50B is provided in place of the switch circuit 50.

### 3.3. Circuit Configuration of Switch Circuit 50B

The switch circuit 50B of the present embodiment is connected between the low-noise amplifier 20 and the radio frequency output terminals 111, 112, and 113. The switch circuit 50B includes a common terminal 500, selection terminals 501, 502, and 503, switches 51, 52, 53, and 55, a splitter 56, and an inductor 57.

The common terminal 500 is an external connection terminal of the switch circuit 50B. The common terminal 500 is connected to the output end of the low-noise amplifier 20 outside of the switch circuit 50B and is connected to the splitter 56 inside of the switch circuit 50B.

The selection terminal 501 is an example of a first selection terminal and is an external connection terminal of the switch circuit 50B. The selection terminal 501 is connected to the radio frequency output terminal 111 outside of the switch circuit 50B and is connected to a terminal 512 of the switch 51 inside of the switch circuit 50B.

The selection terminal 502 is an example of a second selection terminal and is an external connection terminal of the switch circuit 50B. The selection terminal 502 is connected to the radio frequency output terminal 112 outside of the switch circuit 50B and is connected to a terminal 532 of the switch 53 inside of the switch circuit 50B.

The selection terminal 503 is an example of a third selection terminal and is an external connection terminal of the switch circuit 50B. The selection terminal 503 is connected to the radio frequency output terminal 113 outside of the switch circuit 50B and is connected to a terminal 552 of the switch 55 inside of the switch circuit 50B.

The switch 51 is an example of a first switch and is connected between the common terminal 500 and the selection terminal 501. Specifically, the switch 51 includes a terminal 511 connected to an output terminal 562 of the splitter 56 and the terminal 512 connected to the selection terminal 501.

With this configuration, the switch 51 can connect and disconnect the terminals 511 and 512 to and from each other based on control signals from, for example, the RFIC 3a and can thereby connect and disconnect a signal path P1.

The signal path P1 is an example of a first signal path and connects the common terminal 500 to the selection terminal 501. Specifically, the signal path P1 extends from the common terminal 500, via the splitter 56 and the switch 51, to the selection terminal 501.

The switch 52 is an example of a second switch and is connected between the common terminal 500 and a node N1. Specifically, the switch 52 includes a terminal 521 connected to an output terminal 563 of the splitter 56 and a terminal 522 connected to the node N1. In the present embodiment, the terminal 522 of the switch 52 is directly connected to a terminal 531 of the switch 53 and a terminal 551 of the switch 55.

With this configuration, the switch 52 can connect and disconnect the terminals 521 and 522 to and from each other based on control signals from, for example, the RFIC 3b and/or the RFIC 3c and can thereby connect and disconnect a signal path P2.

The signal path P2 is an example of a second signal path and connects the common terminal 500 to the node N1. Specifically, the signal path P2 extends from the common terminal 500, via the splitter 56 and the switch 52, to the node N1.

The node N1 is an example of a first node and is a region on signal paths P2 and P3 to which the inductor 57 is connected. In other words, the node N1 is a region on a path connecting the switches 52 and 53 to each other.

The switch 53 is an example of a third switch and is connected between the node N1 and the selection terminal 502. Specifically, the switch 53 includes the terminal 531 connected to the node N1 and the terminal 532 connected to the selection terminal 502. In the present embodiment, the terminal 531 of the switch 53 is directly connected to the terminal 522 of the switch 52.

With this configuration, the switch 53 can connect and disconnect the terminals 531 and 532 to and from each other based on control signals from, for example, the RFIC 3b and can thereby connect and disconnect a signal path P3.

The signal path P3 is an example of a third signal path and connects the node N1 to the selection terminal 502. Specifically, the signal path P3 extends from the node N1, via the switch 53, to the selection terminal 502.

The switch 55 is an example of a fourth switch and is connected between the node N1 and the selection terminal 503. Specifically, the switch 55 includes the terminal 551 connected to the node N1 and the terminal 552 connected to the selection terminal 503. In the present embodiment, the terminal 551 of the switch 55 is directly connected to the terminal 522 of the switch 52.

With this configuration, the switch 55 can connect and disconnect the terminals 551 and 552 to and from each other based on control signals from, for example, the RFIC 3c and can thereby connect and disconnect a signal path P5.

The signal path P5 is an example of a fourth signal path and connects the node N1 to the selection terminal 503. Specifically, the signal path P5 extends from the node N1, via the switch 55, to the selection terminal 503.

Each of the switches 51 to 53 and 55 is implemented by, for example, an SPST switch circuit. For example, each of the switches 51 to 53 and 55 includes multiple series-connected FETs. Alternatively, each of the switches 51 to 53 and 55 may include only one FET.

The splitter 56 includes an input terminal 561 and output terminals 562 and 563. The input terminal 561 is connected to the common terminal 500. The output terminal 562 is an example of a first output terminal and is connected to the selection terminal 501 via the switch 51. The output terminal 563 is an example of a second output terminal and is connected to the node N1 via the switch 52. The splitter 56 can distribute a radio frequency signal supplied to the input terminal 561 to the signal paths P1 and P2. As a non-limiting example, the splitter 56 may be implemented by a Wilkinson divider or a diplexer. The splitter 56 is not necessarily included in the switch circuit 50B.

The inductor 57 is an example of a first inductor and is connected between the node N1 and the ground. Specifically, a first end of the inductor 57 is connected to the node N1, and a second end of the inductor 57 is connected to the ground.

In the switch circuit 50B as described above, each of the quantity of switches on the signal paths P2 and P3 (two in the present embodiment) and the quantity of switches on the signal paths P2 and P5 (two in the present embodiment) is greater than the quantity of switches on the signal path P1 (one in the present embodiment). With this configuration, each of the off-capacitance of the switches on the signal paths P2 and P3 and the off-capacitance of the switches on the signal paths P2 and P5 is greater than the off-capacitance of the switch on the signal path P1.

Also, the quantity of switches on the signal path P3 (one in the present embodiment) is equal to the quantity of switches on the signal path P5 (one in the present embodiment). Accordingly, the off-capacitance of the switches on the signal paths P2 and P3 is equal to the off-capacitance of the switches on the signal paths P2 and P5.

### 3.4. Multiple Communication Modes

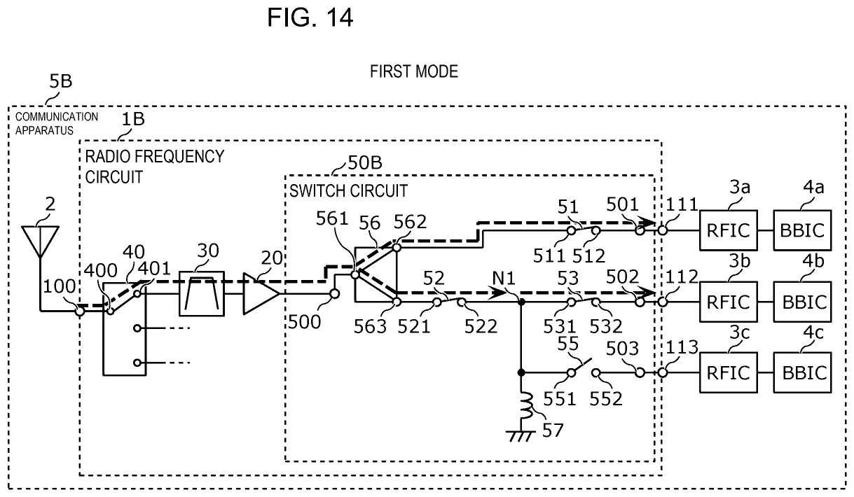

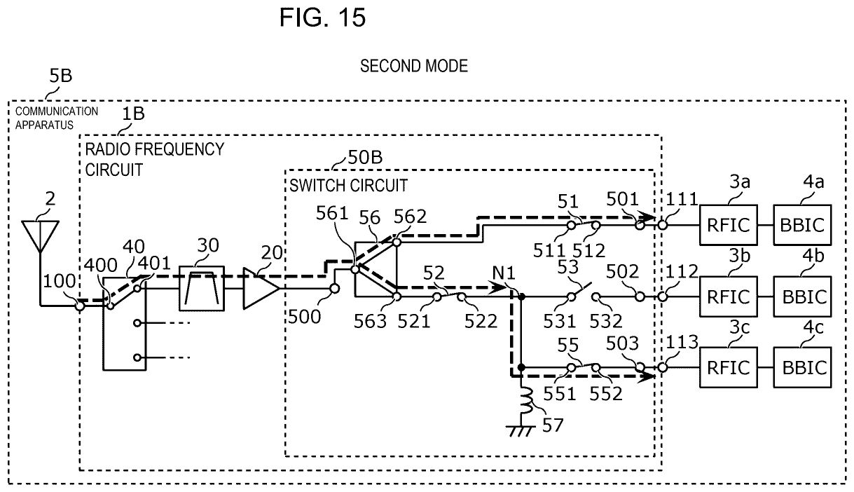

Next, multiple communication modes of the radio frequency circuit 1B are described with reference to FIGS. 14 and 15. In FIGS. 14 and 15, the dashed arrows represent reception paths of radio frequency signals in the corresponding communication modes.

### 3.4.1. First Mode

First, a first mode included in the multiple communication modes of the radio frequency circuit 1B is described with reference to FIG. 14. FIG. 14 is a diagram illustrating the first mode of the radio frequency circuit 1B of the present embodiment.

The first mode is a communication mode for receiving a radio frequency signal (for example, a cellular network signal) to be processed by the RFIC 3a and a radio frequency signal (for example, a WLAN signal) to be processed by the RFIC 3b.

In the first mode, the switch circuit 40 connects the common terminal 400 to the selection terminal 401. Also, the switch circuit 50B connects the common terminal 500 to the selection terminals 501 and 502 but not to the selection terminal 503. Specifically, the switch circuit 50B closes the switches 51, 52, and 53 and opens the switch 55.

As a result, two reception signals are transmitted from the antenna 2, via the antenna connection terminal 100, the switch circuit 40, the filter 30, the low-noise amplifier 20, the switch circuit 50B, and the radio frequency output terminals 111 and 112, to the RFICs 3a and 3b. In the switch circuit 50B, one of the two reception signals is transmitted from the common terminal 500, via the splitter 56 and the switch 51, to the selection terminal 501; and the other one of the two reception signals is transmitted from the common terminal 500, via the splitter 56 and the switches 52 and 53, to the selection terminal 502.

### 3.4.2. Second Mode

Next, a second mode included in the multiple communication modes of the radio frequency circuit 1B is described with reference to FIG. 15. FIG. 15 is a diagram illustrating the second mode of the radio frequency circuit 1B of the present embodiment.

The second mode is a communication mode for receiving a radio frequency signal (for example, a cellular network signal) to be processed by the RFIC 3a and a radio frequency signal (for example, a UWB signal) to be processed by the RFIC 3c.

In the second mode, the switch circuit 40 connects the common terminal 400 to the selection terminal 401. Also, the switch circuit 50B connects the common terminal 500 to the selection terminals 501 and 503 but not to the selection terminal 502. Specifically, the switch circuit 50B closes the switches 51, 52, and 55 and opens the switch 53.

As a result, two reception signals are transmitted from the antenna 2, via the antenna connection terminal 100, the switch circuit 40, the filter 30, the low-noise amplifier 20, the switch circuit 50B, and the radio frequency output terminals 111 and 113, to the RFICs 3a and 3c. In the switch circuit 50B, one of the two reception signals is transmitted from the common terminal 500, via the splitter 56 and the switch 51, to the selection terminal 501; and the other one of the two reception signals is transmitted from the common terminal 500, via the splitter 56 and the switches 52 and 55, to the selection terminal 503.

The multiple communication modes of the radio frequency circuit 1B are not limited to the first and second modes. For example, the multiple communication modes of the radio frequency circuit 1B may include communication modes that are different from the first and second modes.

### 3.5. Summary

As described above, the switch circuit 50B of the present embodiment includes the common terminal 500; the selection terminals 501, 502, and 503; the switch 51 configured to connect and disconnect the signal path P1 between the common terminal 500 and the selection terminal 501; the switch 52 configured to connect and disconnect the signal path P2 between the common terminal 500 and the node N1; the switch 53 configured to connect and disconnect the signal path P3 between the node N1 and the selection terminal 502; the switch 54 configured to connect and disconnect the signal path P4 between the node N1 and the selection terminal 503; and the inductor 57 connected between the node N1 and the ground. Each of the quantity of switches on the signal paths P2 and P3 and the quantity of switches on the signal paths P2 and P4 is greater than the quantity of switches on the signal path P1.

With this configuration, because the inductor 57 is connected to the signal paths P2 and P3 and the signal paths P2 and P5, which have a greater quantity of switches, it is possible to reduce impedance mismatching caused by the difference in the off-capacitance between these signal paths and the signal path P1, which has a smaller quantity of switches. That is, the above configuration makes it possible to reduce the degradation of the transmission characteristics of multiple signal paths with different quantities of switches. Also, because the common inductor 57 is connected to the signal paths P2 and P3 and the signal paths P2 and P5, it is possible to reduce the quantity of inductors compared to a case in which separate inductors are connected to the signal paths P2 and P3 and to the signal paths P2 and P5. That is, the above configuration makes it possible to reduce the size of the switch circuit 50B.

Also, for example, in the switch circuit 50B of the present embodiment, the quantity of switches on the signal path P3 may be equal to the quantity of switches on the signal path P5.

This in turn makes it possible to reduce the difference between the off-capacitance of the switches on the signal paths P2 and P3 and the off-capacitance of the switches on the signal paths P2 and P5 and thereby makes it possible to effectively adjust the impedance using the inductor 57.

Also, for example, in the switch circuit 50B of the present embodiment, the switch 52 may be directly connected to the switches 53 and 54.

With this configuration, the inductor 57 is connected between the ground and the node N1 on the path directly connecting the switch 52 to the switches 53 and 55. This makes it possible to effectively reduce impedance mismatching caused by the off-capacitance of the switches 52 and 53 and the off-capacitance of the switches 52 and 55.

Also, for example, in the switch circuit 50B of the present embodiment, in the first mode, the switches 51, 52, and 53 may be closed, and the switch 54 may be opened; and in the second mode, the switches 51, 52, and 54 may be closed, and the switch 53 may be opened.

With this configuration, the common terminal 500 can be connected to the selection terminals 501 and 502 in the first mode, and the common terminal 500 can be connected to the selection terminals 501 and 503 in the second mode. The inductor 57 makes it possible to reduce the impedance mismatching caused by the difference in the quantity of switches on the signal paths in the first and second modes.

Also, for example, the switch circuit 50B according to the present embodiment may further include the splitter 56 that includes the input terminal 561 connected to the common terminal 500, the output terminal 562 connected to the selection terminal 501 via the switch 51, and the output terminal 563 connected to the node N1 via the switch 52.

This makes it possible to distribute an input signal inputted to the common terminal 500 to two selection terminals.

### Variation of Third Embodiment

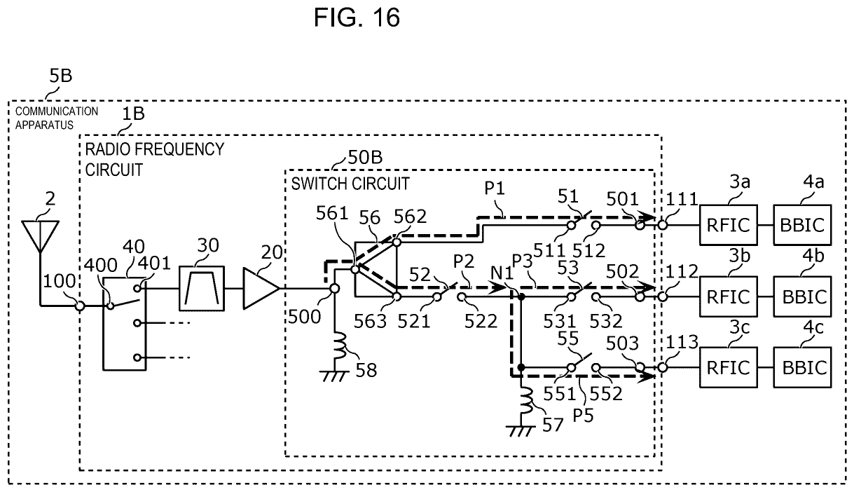

In the circuit configurations of the communication apparatus 5B, the radio frequency circuit 1B, and the switch circuit 50B according to the third embodiment, additional circuit elements and wires may be inserted in paths connecting circuit elements and signal paths illustrated in the diagrams. For example, as illustrated in FIG. 16, the switch circuit 50B according to the variation of the third embodiment may further include an inductor 58.

The inductor 58 is an example of a second inductor and is connected between the common terminal 500 and the ground. Specifically, a first end of the inductor 58 is connected to the common terminal 500, and a second end of the inductor 58 is connected to the ground.

Thus, the switch circuit 50B according to the present variation further includes the inductor 58 connected between the common terminal 500 and the ground.

This makes it possible to further adjust the impedance in multiple signal paths with different quantities of switches and thereby makes it possible to further reduce the degradation of transmission characteristics.

### Fourth Embodiment

Next, a fourth embodiment is described. The present embodiment differs primarily from the first embodiment in that single-pole double-throw (SPDT) switches are connected to the common terminal of the switch circuit and a matching circuit is included in the switch circuit. Below, differences between the first embodiment and the fourth embodiment are mainly described with reference to the drawings.

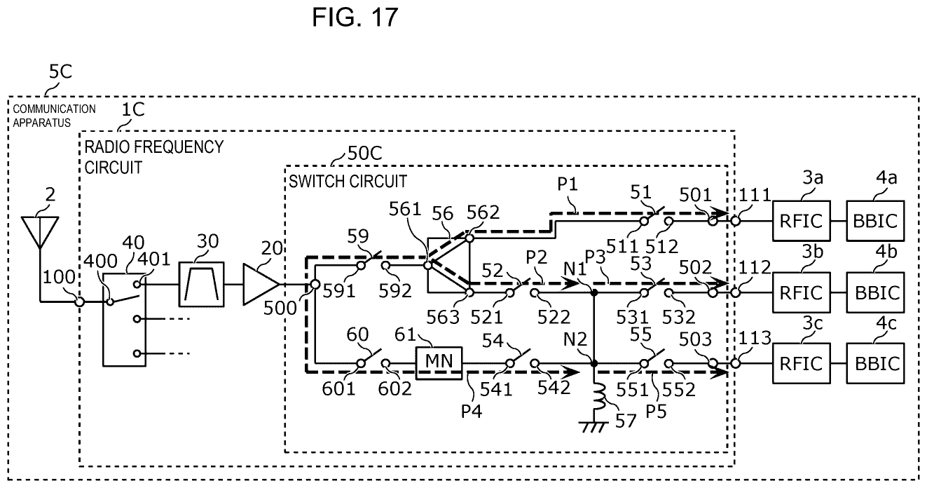

FIG. 17 is a circuit diagram of a communication apparatus 5C according to the present embodiment. In FIG. 17, the dashed arrows represent signal paths.

FIG. 17 is an exemplary circuit diagram, and the communication apparatus 5C, a radio frequency circuit 1C, and a switch circuit 50C may be implemented by using any of various circuit implementations and circuit technologies. Therefore, the descriptions of the communication apparatus 5C, the radio frequency circuit 1C, and the switch circuit 50C provided below should not be interpreted restrictively.

### 4.1. Circuit Configuration of Communication Apparatus 5C

As with the communication apparatus 5 according to the first embodiment, the communication apparatus 5C according to the present embodiment can be used to provide wireless connection. The communication apparatus 5C includes the radio frequency circuit 1C, an antenna 2, RFICs 3a, 3b, and 3c, and BBICs 4a, 4b, and 4c. That is, the communication apparatus 5C differs from the communication apparatus 5 according to the first embodiment in that the radio frequency circuit 1C is provided in place of the radio frequency circuit 1.

### 4.2. Circuit Configuration of Radio Frequency Circuit 1C

The radio frequency circuit 1C of the present embodiment includes a low-noise amplifier 20, a filter 30, switch circuits 40 and 50C, an antenna connection terminal 100, and radio frequency output terminals 111, 112, and 113. That is, the radio frequency circuit 1C differs from the radio frequency circuit 1 according to the first embodiment in that the switch circuit 50C is provided in place of the switch circuit 50.

### 4.3. Circuit Configuration of Switch Circuit 50C

The switch circuit 50C according to the present embodiment is connected between the low-noise amplifier 20 and the radio frequency output terminals 111, 112, and 113. The switch circuit 50C includes a common terminal 500, selection terminals 501, 502, and 503, switches 51, 52, 53, 54, 55, 59, and 60, a splitter 56, an inductor 57, and a matching circuit (matching network) 61.

The switch 59 is an example of a sixth switch and is connected between the common terminal 500 and the input terminal 561 of the splitter 56. Specifically, the switch 59 includes a terminal 591 connected to the common terminal 500, and a terminal 592 connected to the input terminal 561 of the splitter 56.

With this configuration, the switch 59 can connect and disconnect the terminals 591 and 592 to and from each other based on control signals from, for example, the RFIC 3a and/or the RFIC 3b and can thereby connect and disconnect the common terminal 500 and the splitter 56 to and from each other.

The switch 60 is an example of a seventh switch and is connected between the common terminal 500 and the matching circuit 61. Specifically, the switch 60 includes a terminal 601 connected to the common terminal 500 and a terminal 602 connected to the matching circuit 61.

With this configuration, the switch 60 can connect and disconnect the terminals 601 and 602 to and from each other based on control signals from, for example, the RFIC 3b and/or the RFIC 3c and can thereby connect and disconnect the common terminal 500 and the matching circuit 61 to and from each other.

The switches 59 and 60 described above can function as SPDT switches. That is, the switches 59 and 60 are controlled to be selectively closed and not to be closed simultaneously. Specifically, the switches 59 and 60 are controlled such that the switch 60 is opened when the switch 59 is closed, and the switch 59 is opened when the switch 60 is closed.

The matching circuit 61 is connected between the switch 60 and the switch 54. The matching circuit 61 includes, for example, an inductor and/or a capacitor. The matching circuit 61 can achieve impedance matching in the signal circuit P4. The matching circuit 61 is not necessarily included in the switch circuit 50C.

As with the radio frequency circuit 1 according to the first embodiment, multiple communication modes of the radio frequency circuit 1C according to the present embodiment may include the first through fourth modes (FIGS. 4 to 7). In the first mode and the third mode, the switch 59 is closed, and the switch 60 is opened. On the other hand, in the second mode and the fourth mode, the switch 59 is opened, and the switch 60 is closed.

### 4.3. Summary

As described above, the switch circuit 50C according to the present embodiment may further include the switch 59 connected between the common terminal 500 and the input terminal 561 of the splitter 56, and the switch 60 connected between the common terminal 500 and the switch 54.

In communication modes (for example, the second mode and the fourth mode) in which a radio frequency signal is outputted only from the selection terminal 502 or 503 among the selection terminals 501 to 503, this configuration makes it possible to reduce characteristics variation caused by the splitter 56. Specifically, opening the switch 59 in a mode in which the signal path P4 is used makes it possible to reduce the variation in impedance, which is observed when the selection terminal 501 is seen from the selection terminal 502 or 503, due to the splitter 56.

Also, for example, the switch circuit 50C according to the present embodiment may further include the matching circuit 61 connected between the switch 60 and the switch 54.

This makes it possible to achieve impedance matching in the signal path P4.

### Other Embodiments

Switch circuits, radio frequency circuits, and communication apparatuses according to the embodiments of the present disclosure and their variations are described above. However, the present disclosure is not limited to the switch circuits, the radio frequency circuits, and the communication apparatuses according to the above embodiments and their variations. The present disclosure may also include other embodiments implemented by combining components in the above embodiments and variations, other variations obtained by making various modifications conceivable by a person skilled in the art to the embodiments and variations without departing from the spirit of the present disclosure, and various devices including the switch circuits or the radio frequency circuits.

For example, in the circuit configurations of the switch circuits and the radio frequency circuits according to the embodiments and the variations described above, additional circuit elements and/or wires may be inserted in paths connecting the circuit elements or the signal paths illustrated in the drawings. For example, an impedance matching circuit may be connected between the selection terminal 401 of the switch circuit 40 and the filter 30 and/or between the filter 30 and the low-noise amplifier 20. As another example, a coupler may be connected between the common terminal 400 of the switch circuit 40 and the antenna connection terminal 100. As another example, in the switch circuit 50, 50A, or 50B, a switch may be connected between the ground and the path connecting the switch 51 to the selection terminal 501, and a switch may also be connected between the ground and the path connecting the switch 53 to the selection terminal 502. Furthermore, in the switch circuit 50 or 50B, a switch may be connected between the ground and the path connecting the switch 55 to the selection terminal 503.

In the above embodiments and their variations, the inductor 57 is connected to the node N1. Alternatively, any other circuit element capable of cancelling the off-capacitance of switches may be connected to the node N1.

In the above embodiments and their variations, each of the switch circuits 50, 50A, and 50B is used to switch reception paths. Alternatively, each of the switch circuits 50, 50A, and 50B may be used to switch transmission paths.

In this case, each of the radio frequency circuits 1, 1A, and 1B may include a power amplifier instead of, or in addition to, the low-noise amplifier 20.

Features of the switch circuits according to the above embodiments and their variations are described below.
<1> A switch circuit includes a common terminal, a first selection terminal, a second selection terminal, and a third selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the common terminal and a second node; a fifth switch configured to connect and disconnect a fifth signal path between the second node and the third selection terminal; and a first inductor connected between the first node and a ground and is connected between the second node and the ground. Each of the quantity of switches on the second signal path and the third signal path and the quantity of switches on the fourth signal path and the fifth signal path is greater than the quantity of switches on the first signal path.
<2> In the switch circuit described in <1>, the quantity of switches on the second signal path and the third signal path is equal to the quantity of switches on the fourth signal path and the fifth signal path.
<3> In the switch circuit described in <1> or <2>, the second switch is directly connected to the third switch; and the fourth switch is directly connected to the fifth switch.
<4> The switch circuit described in any one of <1> to <3> further includes a second inductor connected between the common terminal and the ground.
<5> In the switch circuit described in any one of <1> to <4>, in a first mode, the first switch, the second switch, and the third switch are closed, and the fourth switch and the fifth switch are opened; in a second mode, the fourth switch and the fifth switch are closed, and the first switch, the second switch, and the third switch are opened; in a third mode, the first switch, the second switch, and the fifth switch are closed, and the third switch and the fourth switch are opened; and in a fourth mode, the third switch and the fourth switch are opened, and the first switch, the second switch, and the fifth switch are closed.
<6> The switch circuit described in any one of <1> to <5> further includes a splitter including an input terminal connected to the common terminal, a first output terminal connected to the first selection terminal via the first switch, and a second output terminal connected to the first node and the second node via the second switch.
<7> The switch circuit described in <6> further includes a sixth switch connected between the common terminal and the input terminal of the splitter; and a seventh switch connected between the common terminal and the fourth switch.
<8> The switch circuit described in <7> further includes a matching circuit connected between the seventh switch and the fourth switch.
<9> In the switch circuit described in any one of <1> to <8>, the first switch, the second switch, the third switch, the fourth switch, the fifth switch, and the first inductor are included in a single integrated circuit.
<10> A switch circuit includes a common terminal, a first selection terminal, and a second selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the common terminal and the first node; and a first inductor connected between the first node and a ground. Each of the quantity of switches on the second signal path and the third signal path and the quantity of switches on the fourth signal path and the third signal path is greater than the quantity of switches on the first signal path.
<11> In the switch circuit described in <10>, the quantity of switches on the second signal path is equal to the quantity of switches on the fourth signal path.
<12> In the switch circuit described in <10> or <11>, the second switch and the fourth switch are directly connected to the third switch.
<13> The switch circuit described in any one of <10> to <12> further includes a second inductor connected between the common terminal and the ground.
<14> In the switch circuit described in any one of <10> to <13>, in a first mode, the first switch, the second switch, and the third switch are closed, and the fourth switch is opened; and in a second mode, the third switch and the fourth switch are closed, and the first switch and the second switch are opened.
<15> The switch circuit described in any one of <10> to <14> further includes a splitter that includes an input terminal connected to the common terminal, a first output terminal connected to the first selection terminal via the first switch, and a second output terminal connected to the first node via the second switch.
<16> In the switch circuit described in any one of <10> to <15>, the first switch, the second switch, the third switch, the fourth switch, and the first inductor are included in a single integrated circuit.
<17> A switch circuit includes a common terminal, a first selection terminal, a second selection terminal, and a third selection terminal; a first switch configured to connect and disconnect a first signal path between the common terminal and the first selection terminal; a second switch configured to connect and disconnect a second signal path between the common terminal and a first node; a third switch configured to connect and disconnect a third signal path between the first node and the second selection terminal; a fourth switch configured to connect and disconnect a fourth signal path between the first node and the third selection terminal; and a first inductor connected between the first node and a ground. Each of the quantity of switches on the second signal path and the third signal path and the quantity of switches on the second signal path and the fourth signal path is greater than the quantity of switches on the first signal path.
<18> In the switch circuit described in <17>, the quantity of switches on the third signal path is equal to the quantity of switches on the fourth signal path.
<19> In the switch circuit described in <17> or <18>, the second switch is directly connected to the third switch and the fourth switch.
<20> In the switch circuit described in any one of <17> to <19>, in a first mode, the first switch, the second switch, and the third switch are closed, and the fourth switch is opened; and in a second mode, the first switch, the second switch, and the fourth switch are closed, and the third switch is opened.

The present disclosure can be widely used for communication devices, such as mobile phones, as a switch circuit disposed in a front-end unit.

What is claimed is:

1. A switch circuit comprising:
a common terminal, a first selection terminal, a second selection terminal, and a third selection terminal;
a first switch configured to connect and disconnect a first signal path between the common terminal and the first selection terminal;
a second switch configured to connect and disconnect a second signal path between the common terminal and a first node;
a third switch configured to connect and disconnect a third signal path between the first node and the second selection terminal;
a fourth switch configured to connect and disconnect a fourth signal path between the common terminal and a second node;
a fifth switch configured to connect and disconnect a fifth signal path between the second node and the third selection terminal; and
a first inductor connected between the first node and a ground and connected between the second node and the ground, wherein
each of a quantity of switches on the second signal path and the third signal path and a quantity of switches on the fourth signal path and the fifth signal path is greater than a quantity of switches on the first signal path.

2. The switch circuit according to claim 1, wherein
the quantity of switches on the second signal path and the third signal path is equal to the quantity of switches on the fourth signal path and the fifth signal path.

3. The switch circuit according to claim 1, wherein
the second switch is directly connected to the third switch; and
the fourth switch is directly connected to the fifth switch.

4. The switch circuit according to claim 1, further comprising:
a second inductor connected between the common terminal and the ground.

5. The switch circuit according to claim 1, wherein
in a first mode, the first switch, the second switch, and the third switch are closed, and the fourth switch and the fifth switch are opened;
in a second mode, the fourth switch and the fifth switch are closed, and the first switch, the second switch, and the third switch are opened;
in a third mode, the first switch, the second switch, and the fifth switch are closed, and the third switch and the fourth switch are opened; and
in a fourth mode, the third switch and the fourth switch are opened, and the first switch, the second switch, and the fifth switch are closed.

6. The switch circuit according to claim 1, further comprising:
a splitter including an input terminal connected to the common terminal, a first output terminal connected to the first selection terminal via the first switch, and a second output terminal connected to the first node and the second node via the second switch.

7. The switch circuit according to claim 6, further comprising:
a sixth switch connected between the common terminal and the input terminal of the splitter; and
a seventh switch connected between the common terminal and the fourth switch.

8. The switch circuit according to claim 7, further comprising:
a matching circuit connected between the seventh switch and the fourth switch.

9. The switch circuit according to claim 1, wherein
the first switch, the second switch, the third switch, the fourth switch, the fifth switch, and the first inductor are included in a single integrated circuit.

10. A switch circuit comprising:
a common terminal, a first selection terminal, and a second selection terminal;
a first switch configured to connect and disconnect a first signal path between the common terminal and the first selection terminal;
a second switch configured to connect and disconnect a second signal path between the common terminal and a first node;
a third switch configured to connect and disconnect a third signal path between the first node and the second selection terminal;
a fourth switch configured to connect and disconnect a fourth signal path between the common terminal and the first node; and
a first inductor connected between the first node and a ground, wherein
each of a quantity of switches on the second signal path and the third signal path and a quantity of switches on the fourth signal path and the third signal path is greater than a quantity of switches on the first signal path.

11. The switch circuit according to claim 10, wherein
a quantity of switches on the second signal path is equal to a quantity of switches on the fourth signal path.

12. The switch circuit according to claim 10, wherein
the second switch and the fourth switch are directly connected to the third switch.

13. The switch circuit according to claim 10, further comprising:
a second inductor connected between the common terminal and the ground.

14. The switch circuit according to claim 10, wherein
in a first mode, the first switch, the second switch, and the third switch are closed, and the fourth switch is opened; and
in a second mode, the third switch and the fourth switch are closed, and the first switch and the second switch are opened.

15. The switch circuit according to claim 10, further comprising:
a splitter that includes an input terminal connected to the common terminal, a first output terminal connected to the first selection terminal via the first switch, and a second output terminal connected to the first node via the second switch.

16. The switch circuit according to claim 10, wherein
the first switch, the second switch, the third switch, the fourth switch, and the first inductor are included in a single integrated circuit.

17. A switch circuit comprising:
a common terminal, a first selection terminal, a second selection terminal, and a third selection terminal;
a first switch configured to connect and disconnect a first signal path between the common terminal and the first selection terminal;
a second switch configured to connect and disconnect a second signal path between the common terminal and a first node;
a third switch configured to connect and disconnect a third signal path between the first node and the second selection terminal;
a fourth switch configured to connect and disconnect a fourth signal path between the first node and the third selection terminal; and
a first inductor connected between the first node and a ground, wherein
each of a quantity of switches on the second signal path and the third signal path and a quantity of switches on the second signal path and the fourth signal path is greater than a quantity of switches on the first signal path.

18. The switch circuit according to claim 17, wherein
a quantity of switches on the third signal path is equal to a quantity of switches on the fourth signal path.

19. The switch circuit according to claim 17, wherein
the second switch is directly connected to the third switch and the fourth switch.

20. The switch circuit according to claim 17, wherein
in a first mode, the first switch, the second switch, and the third switch are closed, and the fourth switch is opened; and
in a second mode, the first switch, the second switch, and the fourth switch are closed, and the third switch is opened.
